(19) United States
(12) Patent Application Publication
(10) Pub. No.: US 2026/0040474 A1
(43) Pub. Date: Feb. 5, 2026

(54) SYSTEMS AND METHODS FOR CARD RETENTION FEATURE RETROFIT

(71) Applicant: Xilinx, Inc., San Jose, CA (US)

(72) Inventors: Ieuan Marshall, Cambridge (GB); Robert Andrew Daniels, Cambridge (GB)

(73) Assignee: Xilinx, Inc., San Jose, CA (US)

(21) Appl. No.: 18/792,738

(22) Filed: Aug. 2, 2024

(51) Int. Cl. H05K 7/14; G06F 1/18

(52) U.S. Cl. CPC H05K 7/1431; G06F 1/185; G06F 1/186; H05K 7/1405

(57) ABSTRACT

A method for card retention feature retrofit can include inserting an end of a first portion of a latch into a slot cut in an edge of a first printed circuit board, wherein the first portion of the latch is arranged to engage with a second portion of the latch on a second printed circuit board, and coupling the first portion of the latch to the first printed circuit board at least in part by aligning one or more first attachment points of a clamp coupled to the end of the first portion of the latch with one or more second attachment points of the first printed circuit board. Various other methods and systems are also disclosed.

### BACKGROUND

A printed circuit board (PCB) can correspond to a medium used in electrical and electronic engineering to connect electronic components to one another in a controlled manner. For example, and without limitation, a PCB can take the form of a laminated sandwich structure of conductive and insulating layers, with each of the conductive layers being designed with an artwork pattern of traces, planes, and other features (e.g., like wires on a flat surface) etched from one or more sheet layers of copper laminated onto and/or between sheet layers of a non-conductive substrate. Electrical components can be fixed to conductive pads on the outer layers in the shape designed to accept the component's terminals, generally by means of soldering, to both electrically connect and mechanically fasten them to it. Another manufacturing process can add vias, such as plated-through holes that allow interconnections between layers. PCBs can be single-sided (e.g., one copper layer), double-sided (e.g., two copper layers on both sides of one substrate layer), or multi-layer (e.g., outer and inner layers of copper, alternating with layers of substrate). Multi-layer PCBs allow for much higher component density because circuit traces on the inner layers would otherwise take up surface space between components.

An expansion card can correspond to a PCB that can be inserted into an electrical connector, or expansion slot (e.g., bus slot) on a computer's motherboard (e.g., backplane) to add functionality to a computer system. For example, and without limitation, an expansion card can be an expansion board, an adapter card, a peripheral card, and/or an accessory card. Sometimes the design of the computer's case and motherboard involves placing most or all of the expansion slots onto a separate, removable card. Typically, such cards are referred to as riser cards in part because they project upward from the board and allow expansion cards to be placed above and parallel to the motherboard.

A card retention feature can correspond to a structural support. For example, the structural support can be a generally planar extension of a PCB that, combined with standardized keep out zones, can assist in holding an expansion card in place and prevent excessive deformation of the expansion card during shock and vibration. For example, and without limitation, a card retention feature can be generally L-shaped so as to extend from the PCB and hook into provisions provided on the card to facilitate the retention mechanism. In this context, a peripheral expansion bus (e.g., peripheral component interconnect (PCI) express) card electromechanical specification contains standards for a “hockey stick” retention feature that is formed of PCB substrate material, with the PCB and “hockey stick” both being formed as one piece of PCB substrate material.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1A is a flow diagram of an example method for card retention feature retrofit.

FIG. 1B is a block diagram illustrating a system for card retention feature retrofit.

FIG. 2 is a plan view of a PCB having one or more attachment points proximate to a slot formed in an edge of the PCB.

FIG. 3 is a rising view of a PCB having one or more attachment points proximate to a slot formed in an edge of the PCB.

FIG. 4 is a plan view of a PCB that includes a plug for connection of the PCB to a factory test fixture.

FIG. 5 is a rising view of a card retention feature with an integral clamp that is configured to attach to a PCB.

FIG. 6 is a rising view of an underside of a PCB having a card retention feature attached thereto by countersunk screws.

FIG. 7 is a view of a card retention feature that includes one or more protrusions and is configured to clip onto a PCB.

FIG. 8 is a view of a card retention feature that includes one or more protrusions that are slanted to protrude more at a first location than at a second location.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Manufacture of PCBs can benefit from testing during and/or after manufacture of the PCBs. For example, a test fixture can be connected to one or more plugs (e.g., of a serial expansion bus of the PCB) to perform the testing. Such test fixtures can be shaped and/or sized differently from expansion card slots. Thus, a test fixture can be prevented from accessing one or more plugs of an expansion card PCB if the PCB has a card retention feature that is positioned at a location blocking access to a plug of the PCB by the text fixture. Without a card retention feature, a PCB design can be unable to accommodate expansion cards that require card retention features. However, adding a card retention feature to a PCB design can require test fixture redesign and/or prevent testing during and/or after manufacture of the PCBs.

The present disclosure is generally directed to systems and methods for card retention feature retrofit. For example, various benefits can be achieved by inserting an end of a first portion of a latch into a slot cut in an edge of a first printed circuit board (e.g., of an expansion card), wherein the first portion of the latch is arranged to engage with a second portion of the latch on a second printed circuit board (e.g., of a motherboard or ninety-degree adapter), and coupling the first portion of the latch to the first printed circuit board at least in part by aligning one or more first attachment points of a clamp coupled to the end of the first portion of the latch with one or more second attachment points of the first printed circuit board. In this context, a test fixture can be successfully connected to a plug of a PCB during and/or after manufacture of the PCB. After testing is complete, the test fixture can be detached from the plug and the card retention feature can be retrofit to the PCB. As a result, the PCBs can accommodate expansion cards that require card retention features and can accommodate testing during and/or after manufacture of the PCBs using test fixtures without requiring test fixture redesign.

Particular benefits can be obtained by using a clamp to attach a card retention feature directly to a PCB. For example, retrofit of a card retention feature (e.g., by a right angled tab) to a heat sink or plastic cover of a PCB can admit mechanical flap of the PCB because forces on the PCB are not caused to remain in a common plane of the PCB and the card retention feature. In contrast, use of a clamp, such as one that engages the PCB from opposite sides and holds thickest parts of the feature and the PCB in a same plane, can cause such forces to remain in this common plane. Reducing or avoiding mechanical flap that can stress the PCB and/or feature in a direction of least thickness can improve card retention and service life. Further, inserting an end of the card retention feature into a slot cut in an edge of the PCB can yield lateral support between the card retention feature and the PCB. This lateral support can assist in causing the forces to remain in the common plane of the PCB and the card retention feature, further improving card retention and service life. Moreover, a retrofit card retention feature can be replaced if damaged, thus reducing replacement costs.

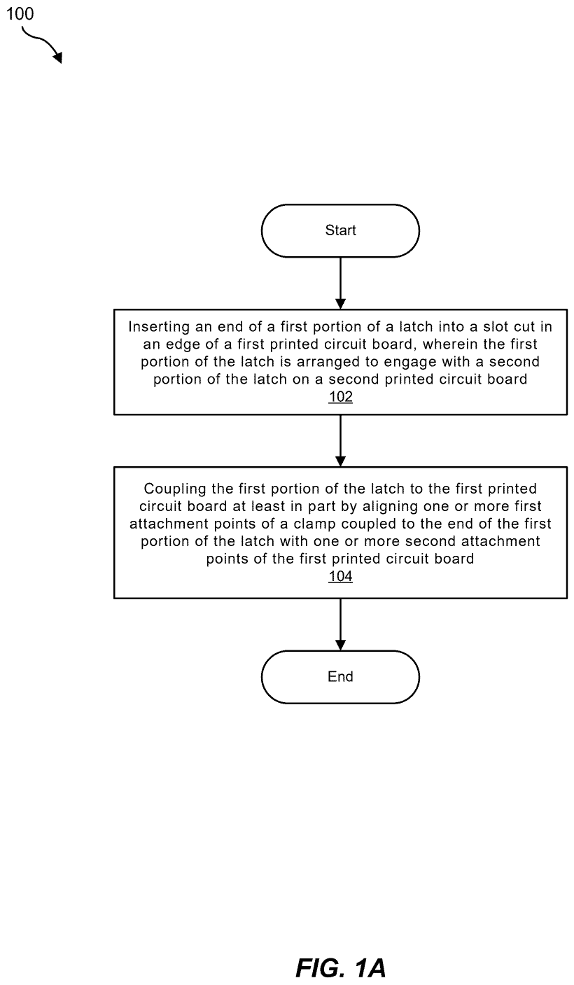

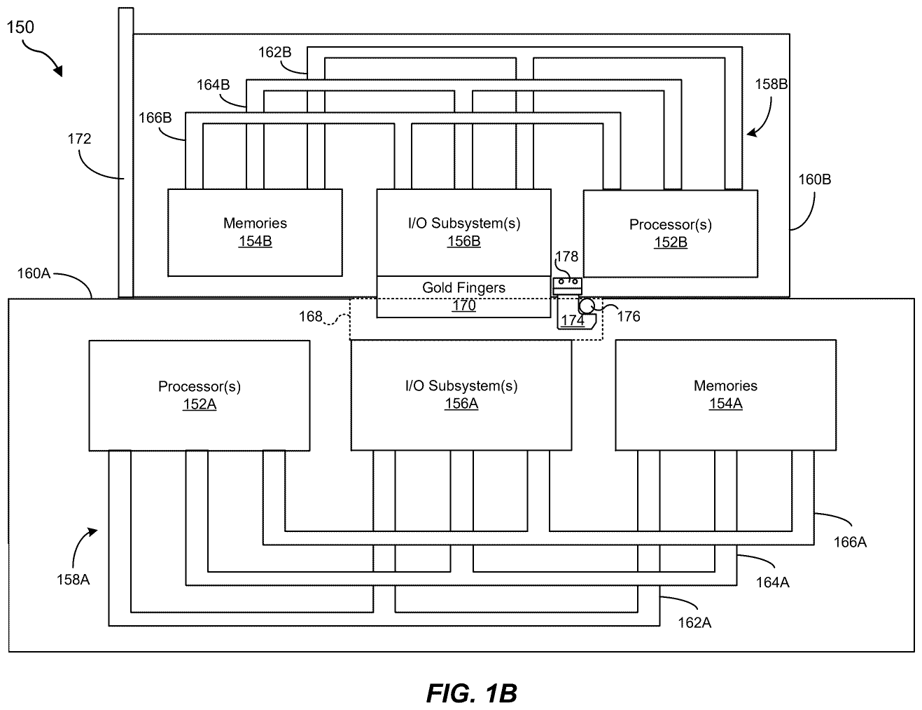

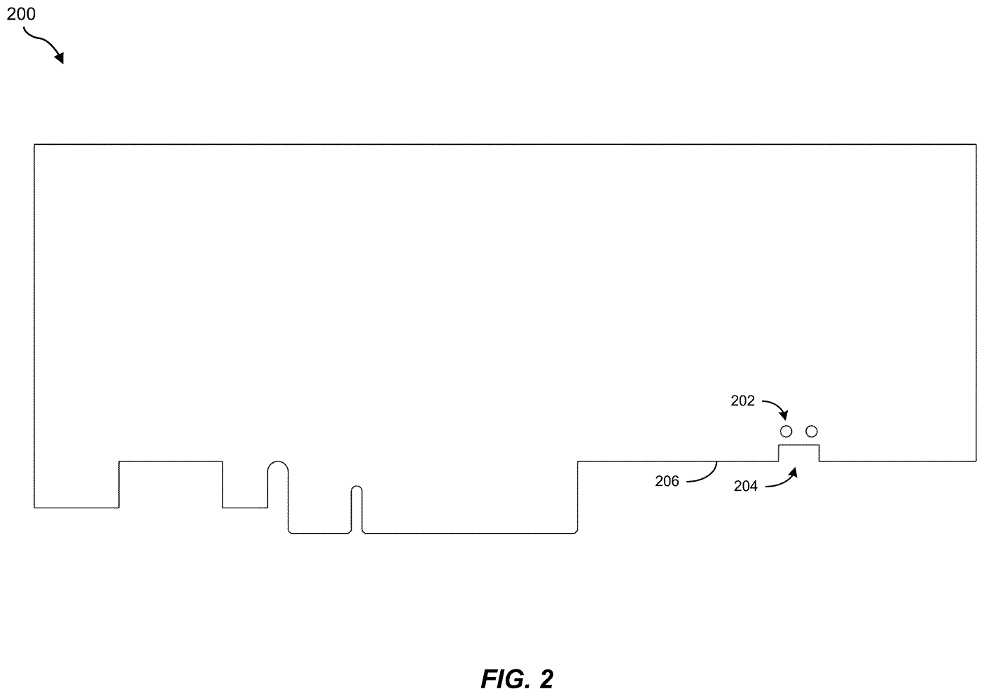

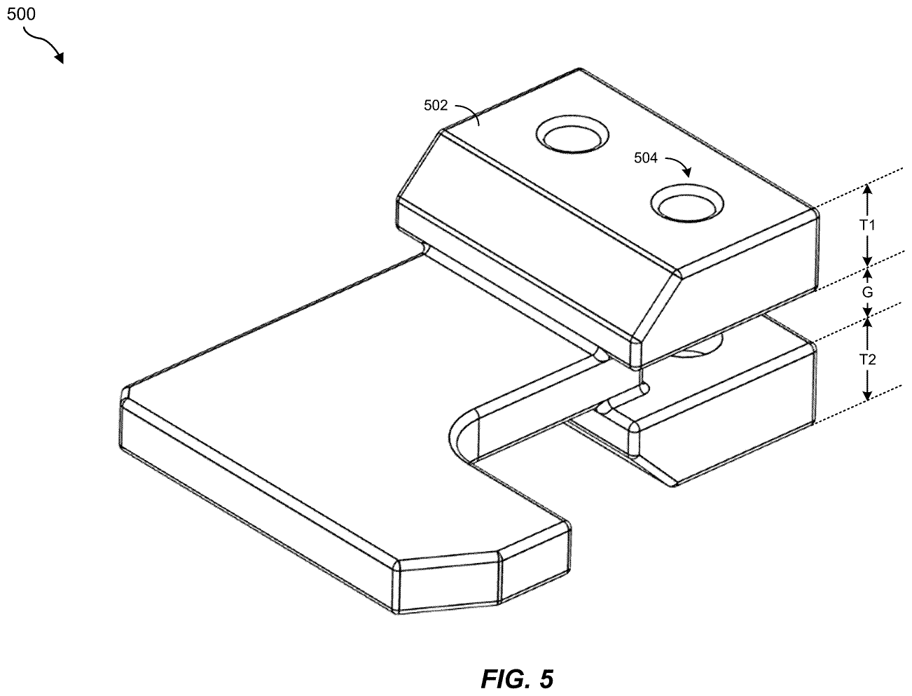

The following will provide, with reference to FIG. 1A, detailed descriptions of example methods for card retention feature retrofit. Detailed descriptions of example systems for card retention feature retrofit will also be provided in connection with FIG. 1B. In addition, detailed descriptions of PCBs configured for card retention feature retrofit will also be provided in connection with FIGS. 2-4. Also, detailed descriptions of example devices facilitating card retention feature retrofit will be provided in connection with FIGS. 5-8.

In one example, a device can include a first portion of a latch having a first end and a second end, wherein the first portion of the latch is arranged to engage with a second portion of the latch on a second printed circuit board to retain a first printed circuit board at a position with respect to the second printed circuit board and a clamp, coupled to the first end of the first portion of the latch, that is configured to attach the first portion of the latch to the first printed circuit board and hold the first portion of the latch in a position outwardly extending from an edge of the first printed circuit board.

Another example can be the previously described example device, wherein the clamp includes one or more first through holes and is configured to be screwed onto the first printed circuit board.

Another example can be any of the previously described example devices, wherein the one or more first through holes are configured to align with one or more second through holes provided in the first printed circuit board when the clamp is inserted into a slot formed in an edge of the first printed circuit board.

Another example can be any of the previously described example devices, wherein the clamp includes one or more protrusions and is configured to clip onto the first printed circuit board.

Another example can be any of the previously described example devices, wherein the one or more protrusions are configured to align with one or more through holes provided in the first printed circuit board when the clamp is inserted into a slot formed in an edge of the first printed circuit board.

Another example can be any of the previously described example devices, wherein the one or more protrusions are slanted to protrude more at a first location closer to the first end than they protrude at a second location further from the first end.

Another example can be any of the previously described example devices, wherein the first portion of the latch corresponds to a peripheral expansion bus hockey stick.

Another example can be any of the previously described example devices, wherein the first portion of the latch and clamp are integrally formed as one piece of material.

In one example, a system can include a first printed circuit board that includes a first circuit and a first communication interface to communicate data to and/or from the first circuit, a second printed circuit that includes a second circuit and a second communication interface to receive the first communication interface and communicate data between the first circuit and the second circuit via the first communication interface, a latch to retain the first printed circuit board at a position with respect to the second printed circuit board, the latch comprising a first portion formed separately from a second portion and configured to interface to retain the first printed circuit board at a position with respect to the second printed circuit board, and a clamp to hold the first portion of the latch to the first printed circuit board.

Another example can be the previously described example system, wherein the first printed circuit board further includes a second interface for connection of the first printed circuit board to test equipment and the first portion of the latch is arranged to block access to the second interface when the clamp holds the first portion of the latch to the first printed circuit board.

Another example can be any of the previously described example systems, wherein the clamp comprises one or more through holes arranged to align with one or more attachment points on the first printed circuit board.

Another example can be any of the previously described example systems, wherein the clamp comprises one or more protrusions arranged to align with one or more attachment points on the first printed circuit board.

Another example can be any of the previously described example systems, wherein the one or more protrusions are slanted to protrude more at a first location than at a second location, the first location being closer than the second location to where the clamp meets the first portion of the latch.

Another example can be any of the previously described example systems, wherein the first portion of the latch corresponds to a peripheral expansion bus hockey stick.

Another example can be any of the previously described example systems, wherein the first portion of the latch and clamp are integrally formed as one piece of material.

Another example can be any of the previously described example systems, wherein the second printed circuit board includes at least one processor, a serial expansion bus connected to the at least one processor, and an expansion card interface connected to the serial expansion bus.

Another example can be any of the previously described example systems, the second printed circuit board is a motherboard, the second communication interface is a peripheral expansion slot arranged to receive the first communication interface of the first printed circuit board, and at least a part of the first communication interface is arranged for insertion into the peripheral expansion slot.

In one example, a method can include inserting an end of a first portion of a latch into a slot cut in an edge of a first printed circuit board, wherein the first portion of the latch is arranged to engage with a second portion of the latch on a second printed circuit board, and coupling the first portion of the latch to the first printed circuit board at least in part by aligning one or more first attachment points of a clamp coupled to the end of the first portion of the latch with one or more second attachment points of the first printed circuit board.

Another example can be the previously described example method, further including uncoupling test equipment from an interface of the first printed circuit board prior to coupling the first portion of the latch thereto, wherein the first portion of the latch is positioned to block access by the test equipment to the interface when the first portion of the latch is coupled to the first printed circuit board.

Another example can be any of the previously described example methods, wherein the one or more first attachment points include one or more through holes and/or one or more protrusions.

FIG. 1A is a flow diagram of an example method 100 for card retention feature retrofit. As illustrated in FIG. 1A, at step 102, method 100 can include positioning inserting an end of a first portion of a latch. For example, method 100 can, at step 102, include inserting an end of a first portion of a latch into a slot cut in an edge of a first printed circuit board, wherein the first portion of the latch is arranged to engage with a second portion of the latch on a second printed circuit board.

Method 100 can perform step 102 in a variety of ways. In some examples, the first portion of the latch can correspond to a peripheral expansion bus hockey stick. In other examples, the first portion of the latch can be formed of plastic material (e.g., thermoplastic, acrylonitrile butadiene styrene (ABS) plastic, nylon, etc.). For example, forming the first portion of the latch of plastic material can be performed using any suitable manufacturing process (e.g., injection molding). In still other examples, the structural support and clamp can be formed of PCB substrate material.

As illustrated in FIG. 1A, at step 104, method 100 can include coupling the first portion of the latch to the first printed circuit board. For example, method 100 can, at step 104, include coupling the first portion of the latch to the first printed circuit board at least in part by aligning one or more first attachment points of a clamp coupled to the end of the first portion of the latch with one or more second attachment points of the first printed circuit board.

Method 100 can perform step 104 in a variety of ways. In some examples, the clamp can include attachment points that correspond to one or more through holes and can be configured to be screwed onto the PCB. In some of these examples, the one or more through holes can be configured to align with attachment points of the first PCB that correspond to through holes provided in the PCB. For example, the one or more through holes of the clamp can align with the one or more through holes of the PCB when the clamp is inserted into a slot formed in an edge of the PCB. In other examples, the clamp can include attachment points corresponding to one or more protrusions (e.g., bumps, posts, flanges, etc.) and can be configured to clip onto the PCB. In some of these examples, the one or more protrusions can be slanted (e.g., continuously slanted) to protrude more at a first location closer to the first end than they protrude at a second location further from the first end. In some of these examples, the one or more protrusions can be configured to align with one or more attachment points of the PCB that correspond to through holes provided in the PCB. For example, the one or more protrusions of the clamp can align with the one or more through holes of the PCB when the clamp is inserted into a slot formed in an edge of the PCB. In still other examples, the attachment points of the clamp can include one or more recesses (e.g., through holes) that can be configured to align with one or more attachment points of the PCB that correspond to protrusions provided in the PCB. For example, the one or more recesses of the clamp can align with the one or more protrusions of the PCB when the clamp is inserted into a slot formed in an edge of the PCB. In some examples, the first portion of the latch and the clamp can be formed as one piece of material (e.g., plastic (e.g., thermoplastic, ABS plastic, nylon, etc.)). For example, forming the first portion of the latch and the clamp of one piece of plastic material can be performed using any suitable manufacturing process (e.g., injection molding).

As illustrated in FIG. 1A, steps 102 and/or 104 of method 100 can include one or more additional sub-steps. In some examples, method 100 can, at steps 102 and/or 104, form a slot (e.g., a rectangular cutout) in an edge of a PCB. The slot, for example, can be sized and shaped to receive a proximal end of the first portion of the latch. Also, a width of the slot can match a width of the proximal end so that walls of the slot can provide lateral support to the first portion of the latch when the proximal end is inserted into the slot. Further, a depth of the slot can be sufficient to allow the clamp to be positioned outside of a keep out zone at the edge of the PCB when the proximal end is inserted into the slot. In other examples, method 100 can, at steps 102 and/or 104, provide a PCB that includes one or more attachment points proximate to a slot formed in an edge of the PCB. Example attachment points can include one or more through holes, one or more recesses, one or more protrusions, combinations thereof, etc. Moreover, the slot and attachment points of the PCB can be located next to a plug of the PCB that can be accessed by a test fixture during testing of a peripheral expansion bus of the PCB.

As illustrated in FIG. 1A, steps 102 and/or 104 of method 100 can include one or more further sub-steps. In some examples, method 100 can, at steps 102 and/or 104, include uncoupling test equipment (e.g., a factory test fixture) from an interface (e.g., a peripheral serial bus plug) of the first printed circuit board prior to coupling the first portion of the latch thereto. For example, the first portion of the latch can be positioned to block access by the test equipment to the interface when the first portion of the latch is coupled to the first printed circuit board.

FIG. 1B illustrates an example system 150 for card retention feature retrofit. For example, system 150 can include one or more processors 152A and/or 152B, one or more memories 154A and/or 154B, and one or more input/output (I/O) subsystems 156A and/or 156B connected by one or more system bus 158A and/or 158B. Processors 152A and/or 152B can include central processing units (CPUs) and/or co-processors, such as graphics processing units (GPUs), accelerator processing units (APUs), arithmetic logic units (ALUs), etc. For example, processors 152A can include one or more CPUs and processors 152B can include one or more co-processors. Memories 154A and/or 154B can correspond to electronic holding places for the instructions and/or data that a computer needs to reach quickly, such as cache memory, main memory, and/or secondary memory.

As shown in FIG. 1B, I/O subsystems 156A and/or 156B can correspond to devices that transfer data to and/or from a computer and control communication between processors 152A and/or 152B and peripheral devices. Peripheral devices can correspond to devices that connect to a core computing unit, such as monitors, mice, keyboards, printers, external memory, expansion cards (e.g. co-processors), etc. In turn, I/O subsystems 156A and/or 156B can include controllers for each of the peripheral devices. One or more processors 152A and/or 152B, one or more memories 154A and/or 154B, and one or more input/output (I/O) subsystems 156A and/or 156B can be implemented as one or more semiconductor device packages connected to one or more printed circuit boards 160A and 160B.

As shown in FIG. 1B, a system bus 158A and/or 158B can be a communication system that transfers data between components inside a computer, or between computers. System bus 158A and/or 158B can include various interconnects, such as data line interconnects 162A and/or 162B, address line interconnects 164A and/or 164B, and control line interconnects 166A and/or 166B. Data line interconnects 162A and/or 162B, in the context of technology and computing, can refer to a communication path that facilitates the transmission of data between devices or systems. Address line interconnects 164A and/or 164B can refer to a physical connection between a CPU/chipset and memory and specify which address to access in the memory. Control line interconnects 166A and/or 166B can receive signals that manage varied chip operations (e.g., scan and write).

As shown in FIG. 1B, system 150 can be implemented with a PCB 160A arranged as a system motherboard that connects to PCB 160B arranged as an expansion card implementing a co-processor, such as a GPU. For this purpose, I/O subsystems 156A of PCB 160A can electrically connect to I/O subsystems 156B of PCB 160B by one or more peripheral serial buses (e.g., PCIe). For example, a peripheral serial bus of PCB 160A can include an expansion card slot 168 and a peripheral serial bus of PCB 160B can include gold fingers 170. In this context, expansion card slot 168 can correspond to a female connector arranged as a receptacle for gold fingers 170, and gold fingers 170 can correspond to a male connector arranged as a protruding edge of PCB 160B with electrical traces (e.g., the gold fingers) thereon.

As shown in FIG. 1B, PCB can have a bracket 172 at an end thereof that can hold that end in a fixed position at an upper corner. Bracket 172 can assist in holding gold fingers 170 in expansion card slot 168 and can be effective in doing so for many low mass expansion cards that lack heat sinks, fans, liquid cooling systems, etc. However, higher mass expansion cards, such as co-processors, can tend to rotate about a pivot point at the bracket 172, which can be affixed to housing that holds PCB 160A. As a result, a right edge of gold fingers 170 can partially retract from expansion card slot 168 when forces are applied in a plane of the PCB 160B. This retraction can degrade or damage electrical traces of expansion card slot 168 and/or gold fingers 170 and consequently adversely affect electrical connection of I/O subsystems 156A and 156B.

As shown in FIG. 1B, system 150 can include a latch that can prevent retraction of the right edge of gold fingers 170 from expansion card slot 168. For example, PCB 160B can include a first portion 174 of the latch and PCB 160A can include a second portion 176 of the latch (e.g., in or proximate to an end of the expansion card slot 168). In some implementations, the first portion 174 of the latch can be a card retention feature (e.g., a hockey stick as defined by one or more peripheral serial bus standards) and the second portion 176 of the latch can be an arm that moves (e.g., rotates, slides, springs, etc.) into a position to retain the card retention feature in a fixed position. For example, a distal end of the first portion 174 of the latch can extend in a direction parallel to a bottom edge of PCB 160B and the arm of the second portion 176 can move into a position between the distal end of the first portion 174 and the PCB 160B.

In other implementations, the first portion 174 and the second portion 176 of the latch can take other forms. For example, although the current peripheral serial bus standards specify use of a hockey stick for the first portion of the latch and leave the second portion of the latch to implementation, these standards may change over time. Thus, the first portion of the latch can correspond to any male or female connector of a latch and be arranged in various ways capable of retaining an expansion card in a fixed position.

As shown in FIG. 1B, the first portion 174 of the latch can include a clamp 178 coupled to a proximal end thereof. This clamp 178 can be used to retrofit the first portion 176 of the latch to the PCB in accordance with example methods detailed above with reference to FIG. 1A. For example, PCB 160B can have a slot cut in a bottom edge of the PCB and attachment points proximate to the slot. The proximal end of the first portion 174 of the latch can insert into the slot and the clamp can attach directly to the PCB 160B at attachment points. In this way, a PCB 160B can accommodate retrofit of a card retention feature to a high mass card after testing so that it does not block access to a plug used for connection of the serial expansion bus to test equipment. Additionally, PCB 160B can accommodate retrofit of a card retention feature to a low mass card in the event that circumstances arise in which a card retention feature can be beneficial (e.g., due to use in high stress environments (e.g., vehicles), due to addition of heat sinks (e.g., for use in high temperature environments), etc.).

As noted above, a peripheral serial bus card retention feature (e.g., as described in the PCIe Card Electromechanical Specification (PCIe CEM spec)) can correspond to an integral feature of the PCB itself. The PCIe hockey stick, for example, is intended to retain PCIe gold edge fingers fully in a server slot for cards that may otherwise dislodge. However, it can be mechanically advantageous for a retro-fit PCIe hockey-stick to attach directly to the PCB itself, as opposed to attaching indirectly by intermediate components capable of relative movement and/or offset from the PCB center plane, such as a heatsink (e.g., that might not be positioned near the required attachment site) or a plastic cover. Additional issues arising in attaching to a heat sink can include freedom of movement inherent to a particular heatsink mounting, extruded heatsink fins being too thin to accept a through hole, and/or manufacturing cost of adding a suitable mount to a heatsink.

The disclosed systems and methods can avoid these issues by attaching a retrofit card retention feature directly to a PCB. A retrofit card retention feature is also advantageous because such card retention features can be undesirable on peripheral serial bus products deployed in a server slot that has no provision for the card retention feature and where it would interfere mechanically. A retrofit card retention feature is additionally advantageous because it can be desirable to add a card retention feature to a card, for example to provide additional retention for an 8-lane (e.g., with no card retention feature) peripheral serial bus card fitted in a retention-compatible peripheral serial bus slot. Such a retrofit card extension feature can correspond to a first portion of a latch having a clamp at one end that is configured to attach to a printed circuit board and hold the first portion of the latch in a position outwardly extending from an edge of the printed circuit board and in a common plane therewith.

In another use case, it could become beneficial to add a card retention feature after an expansion card product has been released without one. For example, with each increasing PCIe generation, signal integrity across the PCIe gold fingers may be affected adversely by any mis-seating or dislodging of the card in the server slot. For cards designed without the hockey-stick card retention feature implemented as standard, the disclosed systems and methods can allow retrofit of a card retention feature directly onto a readied PCB design. Moreover, for PCB designs released without a card retention feature, to then subsequently add the card retention feature permanently to the PCB design can interfere with pre-existing card features (e.g., factory test connectors used during manufacturing tests).

FIG. 2 shows a PCB 200 having one or more attachment points 202 (e.g., recesses, through holes, protrusions, etc.) proximate to a slot 204 (e.g., rectangular cutout) formed (e.g., cut) in an edge 206 (e.g., bottom edge) of the PCB 200. As shown in FIG. 2, the one or more attachment points 202 can correspond to a pair of attachment points located above slot 204. Additionally, slot 204 can be sized and shaped (e.g., keyed) to receive an end of a card retention feature. Also, a width of the slot 204 can match a width of the end so that sides of the slot 204 can provide lateral support to the card retention feature when the end is inserted into the slot 204. Further, a depth of the slot 204 can be sufficient to allow a clamp at the end of the card retention feature to be outside of a keep out zone when the end is inserted into the slot 204.

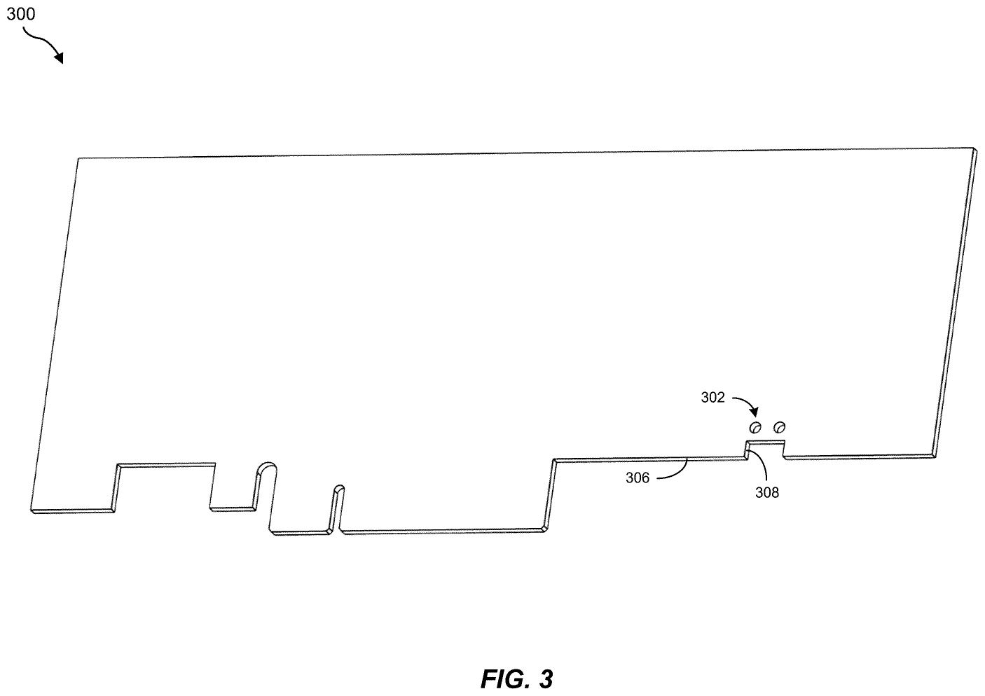

FIG. 3 shows a PCB 300 having one or more attachment points 302 (e.g., through holes) proximate to a slot (e.g., rectangular cutout) formed (e.g., cut) in an edge 306 (e.g., bottom edge) of the PCB 300. As shown in FIG. 3, the one or more attachment points 302 can correspond to a pair of through holes located above the slot. Additionally, the slot can be sized and shaped to receive an end of a card retention feature. Also, a width of the slot can match a width of the end so that sides 308 of the slot can provide lateral support to the card retention feature when the end is inserted into the slot. Further, a depth of the slot can be sufficient to allow a clamp at the end of the card retention feature to be outside of a keep out zone when the end is inserted into the slot.

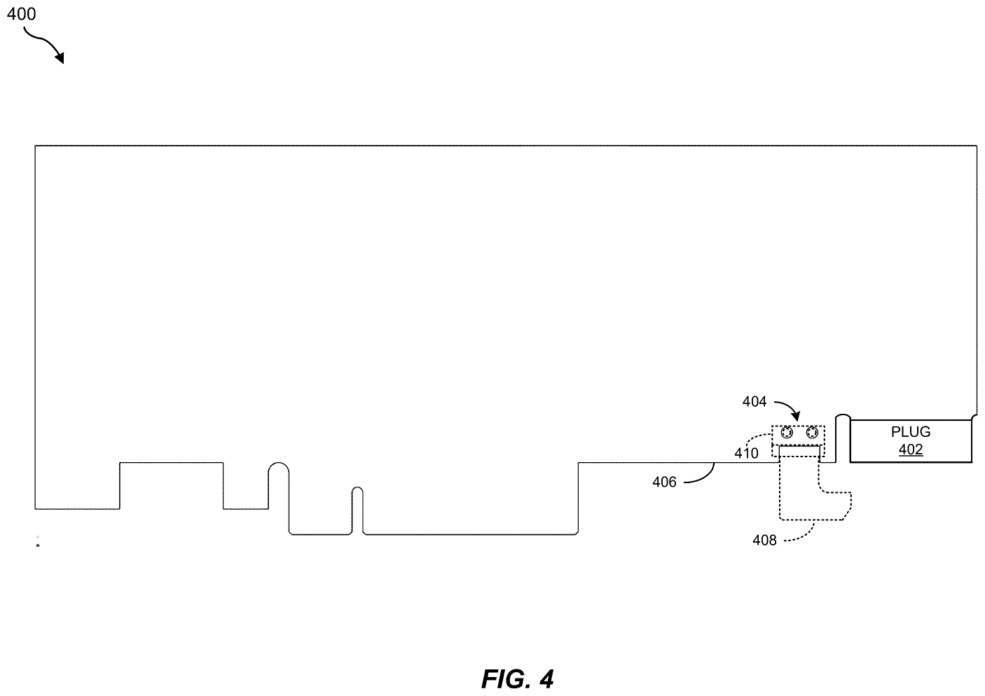

FIG. 4 shows a PCB 400 that includes a plug 402 for connection of a peripheral serial bus of the PCB 400 to a factory test fixture. As shown in FIG. 4, PCB 400 can include one or more attachment points (e.g., recesses, through holes, protrusions, etc.) proximate to (e.g., positioned above) a slot 404 (e.g., rectangular cutout) formed (e.g., cut) in an edge 406 (e.g., bottom edge) of the PCB 400. The slot 404 can be sized and shaped to receive an end (e.g., a proximal end) of a card retention feature 408 having a clamp 410 integrally formed at the end thereof and allow the clamp 410 to rest outside of a keep out zone at the edge 406 of the PCB 400 when the card retention feature 408 is inserted into the slot 404. The clamp can also include one or more attachment points (e.g., through holes, protrusions, recesses, threaded through holes, etc.) configured to align with the one or more attachment points of the PCB 400 when the clamp 410 is inserted into the slot 404. The card retention feature can be configured to block access to the plug 402 when the clamp 410 is inserted into the slot 404. For example, the card retention feature 408 can block access to the plug 402 by a factory test fixture. In this context, another end (e.g., a distal end) of a card retention feature 408 corresponding to a peripheral serial bus hockey stick can be positioned below an access cutout in the PCB 400 that facilitates access to the plug 402. Alternatively or additionally, the other end of the card retention feature 408 can be positioned below at least part of the plug 402.

FIG. 5 shows a card retention feature 500 with an integral clamp 502 at one end that is configured to attach to a PCB. For example, the clamp can include one or more through holes 504 and can be configured to be screwed onto the PCB. The one or more through holes 504 can be configured to align with through holes provided in the PCB when the clamp 502 is inserted into a slot formed in an edge of the PCB. The clamp 502 can include two or more clamp elements (e.g., plates) having respective thicknesses T1 and T2. One or more of thicknesses T1 and/or T2 can be less than or equal to a minimum standardized clearance (e.g., 2.67 mm) for fitting beneath a component (e.g., heat sink) of the PCB. A gap G between the two or more clamp elements can have a size greater than or equal to a standard PCB thickness (e.g., 1.6 mm). A hockey stick of the card retention feature can have a thickness less than or equal to the standard PCB thickness (e.g., 1.6 mm). In some examples, the card retention feature 500 and clamp 502 can be formed as one piece of plastic (e.g., thermoplastic, ABS plastic, nylon, etc.).

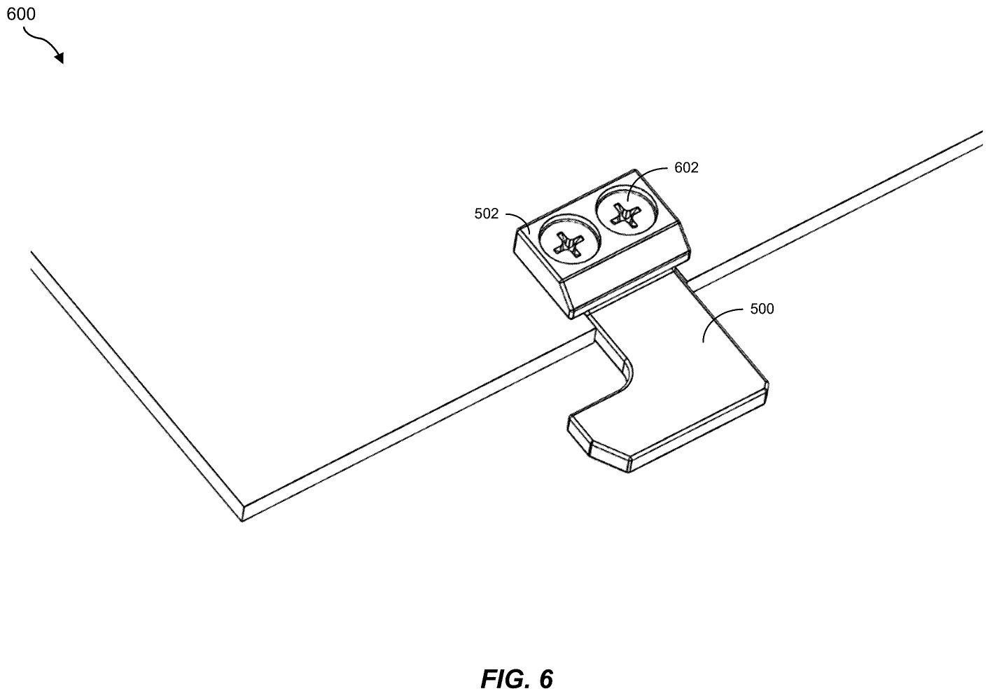

FIG. 6 shows an underside of a PCB 600 having the card retention feature 500 of FIG. 5 attached thereto by countersunk screws 602. Through holes of the clamp 502, for example, can be countersunk so that screws 602 rest at or below a surface of the clamp 502 when the card retention feature 500 is screwed onto the PCB 600. Countersinking of the screws in this manner can assist the clamp in remaining within standard height constraints for PCB 600 components and/or fitting beneath PCB 600 components, such as a heat sink.

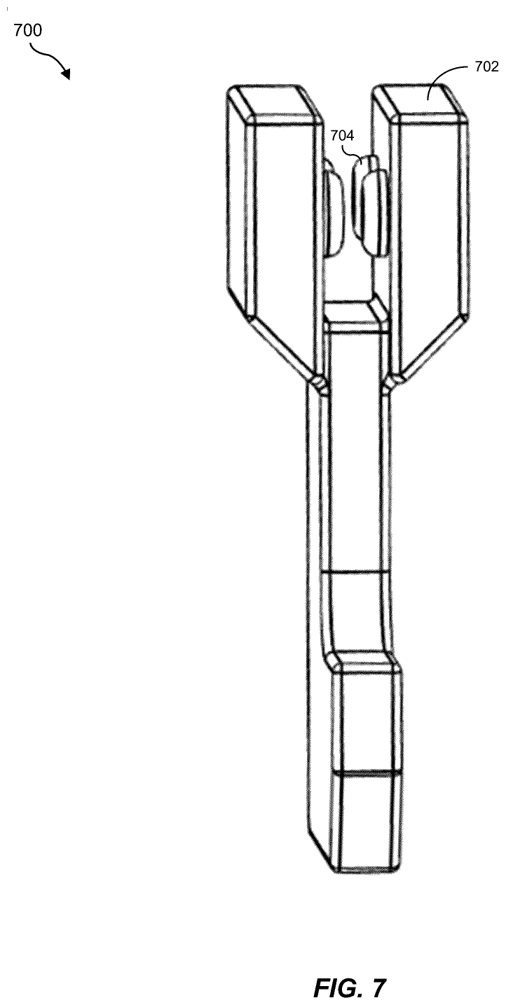

FIG. 7 shows a card retention feature 700 that includes an integral clamp 702 at one end. The integral clamp 702 can include one or more protrusions 704 (e.g., bumps, posts, flanges, etc.) that configure the card retention feature 700 to clip onto a PCB. For example, the clamp 702 integrally formed at an end of the card retention feature 700 can have inwardly facing protrusions 704 that are beveled to facilitate insertion of the card retention feature 700 into a slot of the PCB. The one or more protrusions 704 can be configured to align with one or more recesses and/or through holes provided in the PCB when the clamp 702 is inserted into a slot formed in an edge of the PCB. When the protrusions 704 align with the recesses and/or through holes of the PCB, the protrusions 704 can fit into these attachment points, resulting in a spring fit and/or friction fit of the card retention feature 700 to the PCB. In some examples, the card retention feature 700, the clamp 702, and the one or more protrusions 704 can be formed as one piece of plastic (e.g., thermoplastic, ABS plastic, nylon, etc.).

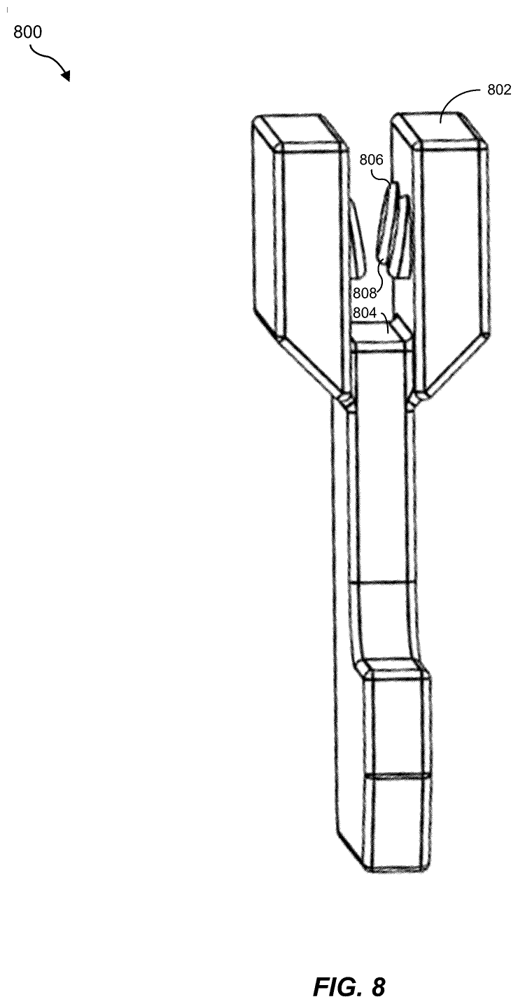

FIG. 8 shows a card retention feature 800 that includes an integral clamp 802 at one end 804. The integral clamp 802 can include one or more protrusions (e.g., bumps, posts, flanges, etc.) that configure the card retention feature 800 to clip onto a PCB. The one or more protrusions can be slanted to protrude more at a first location 806 closer to the end 804 than at a second location 808 further from the end 804. For example, an amount by which the protrusions inwardly protrude can continuously increase from the first location 806 on one side of the protrusions to the second location 808 on an opposite side of the protrusions. Slanting of the protrusions in this manner can facilitate insertion of the card retention feature 800 into a slot of the PCB. The one or more protrusions can be configured to align with one or more recesses and/or through holes provided in the PCB when the clamp 802 is inserted into a slot formed in an edge of the PCB. When the protrusions align with the recesses and/or through holes of the PCB, the protrusions can fit into these attachment points, resulting in a spring fit and/or friction fit of the card retention feature 800 to the PCB. In some examples, the card retention feature 800, the clamp 802, and the one or more protrusions can be formed as one piece of plastic (e.g., thermoplastic, ABS plastic, nylon, etc.).

As set forth above, the disclosed systems and methods can achieve card retention feature retrofit. For example, various benefits can be achieved by inserting an end of a first portion of a latch into a slot cut in an edge of a first printed circuit board (e.g., of an expansion card), wherein the first portion of the latch is arranged to engage with a second portion of the latch on a second printed circuit board (e.g., of a motherboard or ninety-degree adapter), and coupling the first portion of the latch to the first printed circuit board at least in part by aligning one or more first attachment points of a clamp coupled to the end of the first portion of the latch with one or more second attachment points of the first printed circuit board. In this context, a test fixture can be successfully connected to a plug of a PCB during and/or after manufacture of the PCB. After testing is complete, the test fixture can be detached from the plug and the card retention feature can be retrofit to the PCB. As a result, the PCB can accommodate expansion cards that require card retention features and can accommodate testing during and/or after manufacture of the PCBs using test fixtures without requiring test fixture redesign.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a first portion of a latch having a first end and a second end, wherein the first portion of the latch is arranged to engage with a second portion of the latch on a second printed circuit board to retain a first printed circuit board at a position with respect to the second printed circuit board; and
a clamp, coupled to the first end of the first portion of the latch, that is configured to attach the first portion of the latch to the first printed circuit board and hold the first portion of the latch in a position outwardly extending from an edge of the first printed circuit board.

2. The device of claim 1, wherein the clamp includes one or more first through holes and is configured to be screwed onto the first printed circuit board.

3. The device of claim 2, wherein the one or more first through holes are configured to align with one or more second through holes provided in the first printed circuit board when the clamp is inserted into a slot formed in an edge of the first printed circuit board.

4. The device of claim 1, wherein the clamp includes one or more protrusions and is configured to clip onto the first printed circuit board.

5. The device of claim 4, wherein the one or more protrusions are configured to align with one or more through holes provided in the first printed circuit board when the clamp is inserted into a slot formed in an edge of the first printed circuit board.

6. The device of claim 4, wherein the one or more protrusions are slanted to protrude more at a first location closer to the first end than they protrude at a second location further from the first end.

7. The device of claim 1, wherein the first portion of the latch corresponds to a peripheral expansion bus hockey stick.

8. The device of claim 1, wherein the first portion of the latch and clamp are integrally formed as one piece of material.

9. A system, comprising:
a first printed circuit board comprising:
a first circuit; and
a first communication interface to communicate data to and/or from the first circuit;
a second printed circuit board comprising:
a second circuit; and
a second communication interface to receive the first communication interface and communicate data between the first circuit and the second circuit via the first communication interface;
a latch to retain the first printed circuit board at a position with respect to the second printed circuit board, the latch comprising a first portion formed separately from a second portion and configured to interface to retain the first printed circuit board at a position with respect to the second printed circuit board; and
a clamp to hold the first portion of the latch to the first printed circuit board.

10. The system of claim 9, wherein:
the first printed circuit board further includes a second interface for connection of the first printed circuit board to test equipment; and
the first portion of the latch is arranged to block access to the second interface when the clamp holds the first portion of the latch to the first printed circuit board.

11. The system of claim 9, wherein the clamp comprises one or more through holes arranged to align with one or more attachment points on the first printed circuit board.

12. The system of claim 9, wherein the clamp comprises one or more protrusions arranged to align with one or more attachment points on the first printed circuit board.

13. The system of claim 12, wherein the one or more protrusions are slanted to protrude more at a first location than at a second location, the first location being closer than the second location to where the clamp meets the first portion of the latch.

14. The system of claim 9, wherein the first portion of the latch corresponds to a peripheral expansion bus hockey stick.

15. The system of claim 9, wherein the first portion of the latch and clamp are integrally formed as one piece of material.

16. The system of claim 9, wherein: the second printed circuit board includes:
at least one processor;
a serial expansion bus connected to the at least one processor; and
an expansion card interface connected to the serial expansion bus.

17. The system of claim 16, wherein:
the second printed circuit board is a motherboard;
the second communication interface is a peripheral expansion slot arranged to receive the first communication interface of the first printed circuit board; and
at least a part of the first communication interface is arranged for insertion into the peripheral expansion slot.

18. A method, comprising:
inserting an end of a first portion of a latch into a slot cut in an edge of a first printed circuit board, wherein the first portion of the latch is arranged to engage with a second portion of the latch on a second printed circuit board; and
coupling the first portion of the latch to the first printed circuit board at least in part by aligning one or more first attachment points of a clamp coupled to the end of the first portion of the latch with one or more second attachment points of the first printed circuit board.

19. The method of claim 18, further comprising:
uncoupling test equipment from an interface of the first printed circuit board prior to coupling the first portion of the latch thereto,
wherein the first portion of the latch is positioned to block access by the test equipment to the interface when the first portion of the latch is coupled to the first printed circuit board.

20. The method of claim 18, wherein the one or more first attachment points include one or more through holes and/or one or more protrusions.
